(19) United States
(12) Patent Application Publication
(10) Pub. No.: US 2003/0019216 A1
(43) Pub. Date: Jan. 30, 2003

(54) Thermoelectric module, method for making thermoelectric module, thermoelectric device, and fiber floodlight device

(75) Inventors: Masato Itakura, Toyota-shi (JP); Toshihiro Inayoashi, Toyota-shi (JP); Hirotsugu Sugiura, Hekinan-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: AISIN SEIKI KABUSHIKI KAISHA, Kariya-shi (JP)

(21) Appl. No.: 10/161,622

(22) Filed: Jun. 5, 2002

(30) Foreign Application Priority Data
Jun. 5, 2001 (JP) 2001-170041

(51) Int. Cl. F25B 21/02; H01L 35/28

(52) U.S. Cl. 62/3.7; 136/204

(57) ABSTRACT

A thermoelectric module includes a first board having a first electrode, a second board having a second electrode opposing the first electrode, and a plurality of thermoelectric chips made of thermoelectric material, each outer surface of the thermoelectric chips being plated with an Ni system plating layer. The thermoelectric module is characterized in that the Ni system plating layer of the thermoelectric chip is joined to the first electrode of the first board and the second electrode of the second board by a lead free solder layer for connecting each thermoelectric chip disposed between the first electrode of the first board and the second electrode of the second board with the first electrode of the first board and the second electrode of the second board and that the lead free solder layer is comprised of Sn system Sn—Sb system alloy containing Sb of 6-15% by weight and a reinforcing layer of Ni—Sn—Sb system alloy is formed between the lead free solder layer and the Ni system plating layer.

### CROSS REFERENCE OF RELATED APPLICATION

This application is based on and claims priority under 35 U.S.C. ξ119 with respect to Japanese Patent Application No. 2001-170041 filed on Jun. 5, 2001, the entire content of which is incorporated herein by reference.

### FIELD OF THE INVENTION

This invention relates to a thermoelectric module having a thermoelectric chip which converts thermo energy into electric energy, and a method for making the thermoelectric module. Furthermore, the present invention pertains a thermoelectric device which is installed with a thermoelectric module and a fiber floodlight device which is installed with a thermoelectric device.

BACKGROUND OF THE INVENTION

In Japanese Patent Laid-Open Publication No. H10-229223, a method for increasing an area of a solder joining portion to improve connecting strength by forming a chamfered portion at a corner of a thermoelectric chip is disclosed. According to the known method, by developing a lead-free chip, connecting strength of the thermoelectric chip can be improved. However, it is difficult to form a chamfer for a small corner of a surface of the thermoelectric chip by machine work. Furthermore, some of the basic functions of the thermoelectric chip may be impaired because of the chamfering by machine work.

Also, in another Japanese Patent Laid-Open Publication No. H5-299777, a fiber floodlight device is disclosed. According to the Japanese Patent Laid-Open Publication No. H5-299777, the known fiber floodlight device is mounted with a thermoelectric module with a cooling function by an electrical supply. FIG. 1 schematically illustrates this thermoelectric module 2 with the fiber floodlight device. This thermoelectric module 2, as shown in FIG. 1, has a first board 22 which is made of ceramics, containing a first electrode 21, a second board 24 which is made of ceramics, containing a second electrode 23 opposing the first electrode 21, and a plurality of thermoelectric chips 25 which are made of thermoelectric material. According to the known thermoelectric module 2, as shown in FIG. 2 thereof, one 30A of the Ni system plating layers 30 which is layered on an outer surface of each thermoelectric chip is joined to the first electrode 21 of the first board 22 with a solder layer 27 for joining the thermoelectric chips. Similarly, the other 30B of the Ni system plating layers 30, which is layered on the surface of each thermoelectric chip 25 is joined to the second electrode 23 of the second board 24. The thermoelectric module 2 is generally formed based on this structure having a plurality of such Ni system plating layers 30 (30A, 30B). As shown in FIG. 3, a first intermediary Ni system solder layer 41 and a second intermediary solder layer 42 which is made of gold are layered on the first electrode 21 of the first board 22. The solder layer 27 for joining the thermoelectric chips is formed with Sn—Pb system alloy

FIG. 6(A) shows a fiber floodlight device 1 which is mounted with the thermoelectric module 2. According to this fiber floodlight device 1 shown in FIG. 6(B), the device 1 has a package 5 and a heat transfer block 6 which is used for cooling a laser diode 80. In order to assemble the fiber floodlight device, as clearly shown in FIG. 6(B), the first board 22 of the thermoelectric module 2 and the package 5 are joined by a first solder layer 71, and the second board 24 of the thermoelectric module and a joining surface 60 of the heat transfer block 6 are joined by a second solder layer 72.

As specified above, the solder layer 27 for joining the thermoelectric chips which join the thermoelectric chip 25 of the thermoelectric module 2, the first solder layer 71, and the second solder layer 72 are generally formed with a solder alloy containing Pb. Although a solder alloy containing Pb has some advantages such as in flow properties and connecting strength, the influence of Pb on the environment is critical. For instance, if a device which contains the thermoelectric module 2 is wasted in a waste ground, there is a possibility that Pb may pollute the soil. Therefore, with respect to the solder layer 27 which joins the thermoelectric chip 25, the first solder layer 71, and the second solder layer 72, there has been an attempt to develop a lead-free solder material which does not contain Pb.

With respect to the fiber floodlight device 1, when soldering, the thermoelectric module 2 is prepared. The thermoelectric module 2 is mounted with the thermoelectric chip 25 which is joined to the first board 22 and to the second board 24 with the solder layer 27 for joining the thermoelectric chips. Then, the first board 22 of the thermoelectric module 2 and a mounting surface 50 of the package 5 are joined by the second solder layer 71, and the second board 24 of the thermoelectric module 2 and a joining surface 60 of the heat transfer block 6 are joined by the second solder layer 72 When soldering the above portions, a heater 90 is placed on an outer surface 5f of the package 5, and the package 5. the thermoelectric module 2, and the heat transfer block 6 are heated by activating the heater 90. By this heat, solder material for the first solder layer 71 and the second solder layer 72 are melted, and the first solder layer 71 and the second solder layer 72 are formed. In this case, considering the location of the heater 90, the temperature of the first solder layer 71, which is closest to the heater 90, becomes the highest, temperature of the second solder layer 72, which is the furthest to the heater 90 becomes the lowest, and temperature of the thermoelectric module 2 becomes an intermediate temperature of the temperature of the solder layer 71 and the solder layer 72.

When soldering, if the solder layer 27, which joins the thermoelectric chip 25 mounted on the thermoelectric module 2, is melted inadvertently, the thermoelectric chip 25, which comprises the thermoelectric module 2, may move away from its proper position, and this may cause a disconnection of the electrical connection of these devices and possible malfunctions of the performance of the thermoelectric module 2.

Consequently, assuming a temperature Tm as a high temperature for melting the solder layer 27 which joins the thermoelectric chip 25, a temperature T1 as a temperature of melting the first solder layer 71, and a temperature T2 as a temperature of melting in the second solder layer, the relationship among them is established as Tm (solidus temperature)>T1(liquidus temperature)≧T2(liquidus temperature) (this relation is not known at the time of the application of the present invention). By this temperature relationship, even if the temperature of the heater 90 changes from a target temperature, a concern about inadvertent melting of the solder layer 27 which is joining the thermoelectric chip 25 in the thermoelectric module 2 can be cleared.

However, if the solder layer 27 is formed with soldering material whose melting point is high, the temperature for soldering when assembling the chip 25 of the thermoelectric module 2 inevitably becomes high. Therefore, when bringing down to a normal temperature after soldering, an amount of cooling shrinkage of the solder layer 27 would increase, and the frequency of peeling of a joining surface of the thermoelectric chip 25 would also increase. In other words, the connecting strength of the thermoelectric chip 25 is not necessarily strong enough. When the peeling occurs, the basic functions of the thermoelectric chip 25 cannot be fully performed.

### SUMMARY OF THE INVENTION

This invention was made in consideration of the above circumstances, and one of the purposes of this invention is to provide a thermoelectric module which is improved with connecting strength of a thermoelectric chip, a method for making the thermoelectric module, a thermoelectric device, and a fiber floodlight device while developing lead-free of a solder layer for joining the thermoelectric chips of the thermoelectric module.

The inventors of the application developed the lead-free (unleaded) solder layer for joining the thermoelectric chips of the thermoelectric module, the thermoelectric device, and the fiber floodlight device while developing an improvement of the connecting strength of the thermoelectric chips. The inventors discovered that, by covering or coating the thermoelectric chips, which are made of thermoelectric material, with an Ni system plating layer, and by enriching Sb to the solder layer for joining the thermoelectric chips to electrodes of a first board and a second board as an Sn—Sb system alloy of Sn based containing 6-15% of Sb by weight, an alloyed reinforcing layer of Ni—Sn—Sb system can be formed between the solder layer for joining the thermoelectric chips and the Ni system plating layer, achieving lead-free of the solder layer for joining the thermoelectric chips, and improving the connecting strength of the thermoelectric chips.

Although the reason for the improvement of the connection strength by enriching Sb is not clear, it is presumed that if 6-15% of Sb by weight is contained in the Sn—Sb system alloy of the Sn based, Sb is diffused into a surface of the Ni system plating layer of the thermoelectric chips with Sn, which is also contained in the solder layer, maintaining an amount of diffusion of Sb, and the alloyed reinforcing layer of the Ni—Sn—Sb system which is effective in improving the connecting strength is formed. Thus, it is presumed that the connecting strength of the thermoelectric chips of the thermoelectric module is improved by the alloyed reinforcing layer.

More specifically, the thermoelectric module with respect to this invention has the first board which has the first electrode, the second board which has the second electrode opposing the first electrode, and a plurality of the thermoelectric chips made of thermoelectric material, each outer surface of the thermoelectric chips is plated with an Ni system plating layer. The thermoelectric module is characterized in that the Ni system plating layer of the thermoelectric chip is joined to the first electrode of the first board and the second electrode of the second board by a lead free solder layer for connecting each thermoelectric chip disposed between the first electrode of the first board and the second electrode of the second board with the first electrode of the first board and the second electrode of the second board and that the lead free solder layer is comprised of Sn system Sn—Sb system alloy containing Sb of 6-15% by weight and a reinforcing layer of Ni—Sn—Sb system alloy is formed between the lead free solder layer and the Ni system plating layer.

A method for making the thermoelectric module comprises the steps of preparing a first board having a first electrode, a second board having a second electrode opposing the first electrode, a plurality of thermoelectric chips made of thermoelectric material, each outer surface of the thermoelectric chips being plated with an Ni system plating layer and having a non-plating side surface without being plated with the Ni system plating layer, a lead free solder material comprised of Sn system Sn—Sb system alloy containing Sb of 6-15% by weight and a reinforcing layer of Ni—Sn—Sb system alloy for joining the thermoelectric chip, and joining the Ni system plating layer of the thermoelectric chips by soldering with the lead free solder material with the first board having the first electrode and the second board having the second electrode for placing the thermoelectric chips between the first board having the first electrode and the second board having the second electrode and electrically connecting the thermoelectric chips to the first board having the first electrode and the second board having the second electrode to form the thermoelectric module. The method for making the thermoelectric module is characterized in that the method forms a first reinforcing layer of Ni—Sn—Db system alloy between a solder layer formed by the melted and solidified soldering material and the Ni system plating layer, and the method also forms a second reinforcing layer of diffused Sb from the soldering material to an edge of the non-plating side surface of the thermoelectric chip by forcibly contacting the soldering material with the edge of the non-plating side surface of the thermoelectric chip.

A thermoelectric device having the thermoelectric module according to claim 1 or 2 has a package having an mounting surface for mounting the thermoelectric module and a heat transfer block for heating or cooling an object mounted thereon, and the thermoelectric device is comprised of the first solder layer for joining the first board of the thermoelectric module with the mounting surface of the package and a second solder layer for joining the second board of the thermoelectric module with the heat transfer block. The thermoelectric device is characterized in that, each temperature relation is defined by Tm>T1≧T2 wherein Tm represents a temperature for melting the soldering material for joining the thermal chips, T1 represents a temperature for melting the first solder layer and T2 represents a temperature for melting the second solder layer.

The liquidus temperature means a solidification starting point temperature when a melting metal starts to solidify as temperature falls. The solidus temperature means a solidification ending point temperature when the melting metal completes the melting as temperature falls. The solidus temperature corresponds to a temperature when solid metal starts to melt as temperature rises. In addition, if solder material is a eutectic composition, eutectic temperature becomes the solidus temperature and liquidus temperature.

The thermoelectric device with respect to this invention has the package which contains the thermoelectric module, which performs cooling or heating action by an electrical supply, and other than a fiber floodlight device which is to be hereinafter described, a compact cooling device which applies a cooling action, a compact heating device which applies a heating action, and a compact temperature adjustment device can be exemplified. The subject which is to be mounted on the heat transfer block is a laser diode and the LSI but not limited thereto.

A fiber floodlight device with respect to this invention has the thermoelectric module, the mounting surface of which mounts the thermoelectric module, the package which is mounted with a fiber inserting hole which is used for inserting an optical fiber, and the heat transfer block which is used for mounting and cooling light emitting elements, which directs incident laser beam to an optical fiber, which is inserted through the fiber inserting hole, characterized in that the first board of the thermoelectric module and a surface which mounts the package are soldered by the first solder layer, and the second board of the thermoelectric module and the heat transfer block are soldered by the second solder layer.

A floodlight device using the thermoelectric device according to one aspect of the invention, the package for mounting the thermoelectric module further includes a fiber inserting hole for inserting an optical fiber therethrough, the heat transfer block further includes a light emitting element for emitting laser beam to the optical fiber inserted in the fiber inserting hole.

According to the thermoelectric module, the method for making the thermoelectric module, the thermoelectric device, and the fiber floodlight device with respect to this invention, the alloyed reinforcing layer of the Ni—Sn—Sb system, which is effective in improving connecting strength, is formed between the solder layer which solders the thermoelectric chips and the Ni system plating layer in the thermoelectric device. For the soldering material which comprises the solder layer for joining the thermoelectric chips, if Sb is less than 6% by weight, because an amount of diffusion of Sb to the alloyed reinforcing layer falls short, the alloyed reinforcing layer of the Ni—Sn—Sb system would not be formed well, and the improvement of the connecting strength of the chips cannot be expected. On the other hand, if Sb exceeds 15% by weight, wettability of the solder material will be reduced, and it becomes difficult to treat soldering properly. In addition, content of Sb in the solder layer for soldering the chips can be selected to be 7-15% or 8-14% in accordance with the connecting strength required and wettability or wetting performance of soldering material to be used.

According to the thermoelectric module, the method for making the thermoelectric module, the thermoelectric device, and the fiber floodlight device with respect to this invention, the thermoelectric chips can adopt a system which has a side face which is not plated with the Ni system plating layer. The non-plated side face is formed with base metal of the thermoelectric chips. In this case, the solder layer for joining the thermoelectric chips of the thermoelectric module can adopt a system in which the solder layer for joining the thermoelectric chip is directly in contact with an edge of the non-plated side face of the thermoelectric chip. In this case, reinforcement of the edge of the thermoelectric chip can be achieved by forming a second alloyed reinforcing layer in which alloying elements (Sb) of the solder layer for joining the thermoelectric chips are diffused at the edge of the non-plated side face of the thermoelectric chip.

The thermoelectric chips can be formed with an alloy of Bi—Te system. For instance, Bi can be 5-60% or 40-55% occasionally, and Te can be 30-70% and 40-60% occasionally. Also, elements such as Sb or Se can be added if needed.

### BRIEF DESCRIPTION OF THE DRAWINGS

The foregoing and additional features and characteristics of the present invention will become more apparent from the following detained description considered with reference to the accompanying drawings in which like reference numerals designate like elements:

FIG. 1 is a cross-sectional view of a thermoelectric module according to a first embodiment of the present invention showing the structure schematically;

FIG. 2 is a cross-sectional view of a thermoelectric chip according to the present invention showing the condition that the chip is about to be joined to a first electrode of a first board;

FIG. 3 is a schematic cross-sectional view of the thermoelectric chip after being joined to the first electrode of the first board;

FIG. 4 is a cross-sectional view of a relevant part of the thermoelectric chip being diffused after being joined to the first electrode of the first board, which is shown schematically;

FIG. 5 is a cross-sectional view of the thermoelectric chip after being joined to a second electrode of a second board, which is shown schematically;

FIG. 6(A) is a cross-sectional view of an internal structure of a fiber floodlight device, and FIG. 6(B) is its enlarged view; and

FIG. 7 is a cross-sectional view of the thermoelectric chip according to a second embodiment of the present invention being diffused after being joined to the first electrode of the first board, which is shown schematically.

### DETAILED DESCRIPTION OF THE INVENTION

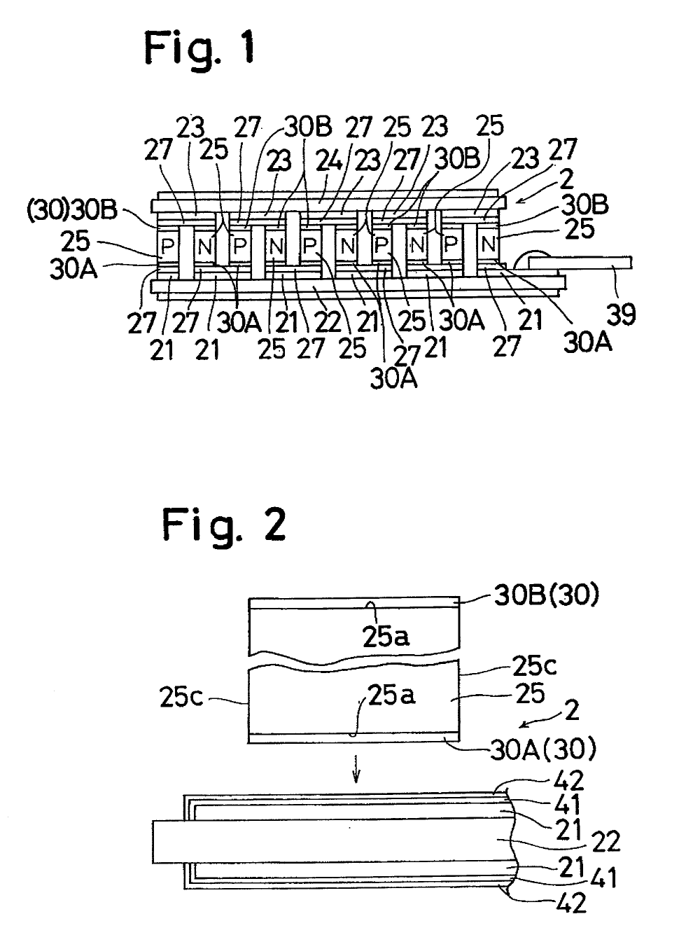

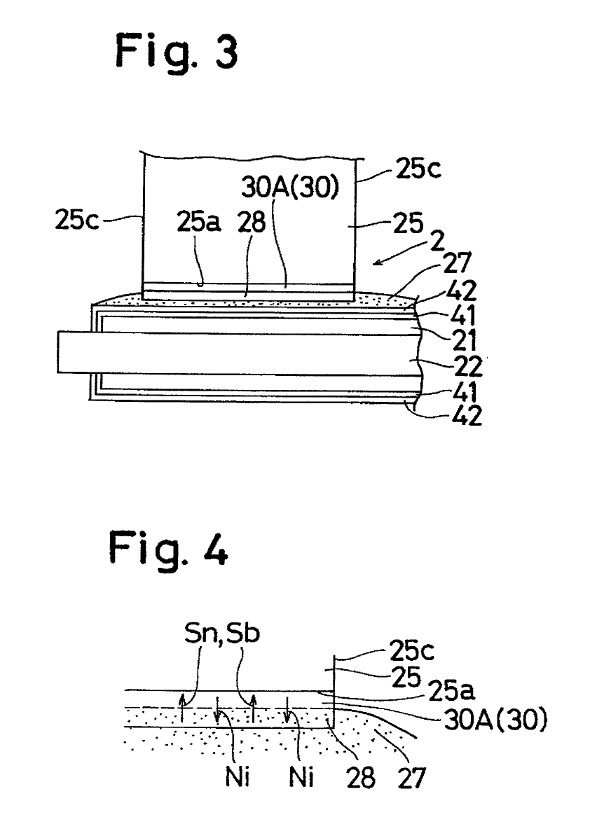

Embodiments of this invention will be described with reference to FIG. 1 through FIG. 6. It should be noted that the structure of the thermoelectric module and the fiber floodlight device of the embodiments shown in the attached drawings are basically identical with the structure of the known thermoelectric module and fiber floodlight device explained in the known art above but different in composite/material to be used or other features claimed in this invention. FIG. 1 shows a thermoelectric module 2 with respect to a first embodiment of this invention. FIGS. 2 and 3 show relevant parts of the thermoelectric module 2 according to the first embodiment of the invention. As shown in FIG. 1, the thermoelectric module 2 has a first board 22, which is made of ceramics (alumina) containing a first electrode 21, which is formed with copper or a copper alloy, a second board 24, which is made of ceramics (alumina) containing a second electrode 23 which is made of copper or a copper alloy opposing the first electrode, and a plurality of thermoelectric chips 25 which are made of thermoelectric material.

The thermoelectric chip 25 is formed with a Bi—Te system alloy, and Bi is contained 5-6%, and Te is contained 40-55% by weight. A size of the thermoelectric chip 25 can be selected accordingly, for instance, 0.7 mm×0.7×1 mm. However, the size of the thermoelectric chip 25 is not limited to this size. P-type and N-type of the thermoelectric chips 25 are aligned alternately, and they are electrically connected in series. If the thermoelectric chip 25 is of P-type, Bi—Te—Sb system is adopted, and if it is N-type, Bi—Te—Se system is adopted. Although thickness of the first electrode 21 can be selected accordingly, it can be 10-70 μm. Similarly, thickness of the second electrode 23 can be selected accordingly, but it can be 10-70 μm.

As shown in FIG. 2, a trailing surface 25a, which is trailing each other, of the thermoelectric chip 25 is covered by an Ni system plating layer 30 (30A, 30B). The Ni system plating layer 30 (30A, 30B) is formed with an electroplating or an electro-less plating. Thickness of the Ni system plating layer 30 (30A, 30B) can be selected accordingly, and it can be 2-50 μm.

Solderability of the thermoelectric chip 25 of the Bi—Te system is not essentially strong in its nature. For this, the improvement of the soldering performance of the thermoelectric chip 25 is reinforced by covering the trailing surface 25a of the thermoelectric chip 25 with the Ni system plating layer 30 which has strong solderability. Furthermore, if Sn of a solder layer 27 for joining the thermoelectric chips is diffused in large quantity into base metal of the thermoelectric chip 25, basic performance of the thermoelectric chip 25 decreases. However, the Ni system plating layer 30 has a function of barrier which keeps the thermoelectric chip 25 from the diffusion of Sn, making the thermoelectric chip 25 easier to maintain its basic performance. The thermoelectric chip 25 contains a non-plated side face 25c which opposes each other and is not covered by the Ni system plating layer 30. The non-plated side face 25c is formed showing the base plate of the thermoelectric chip 25.

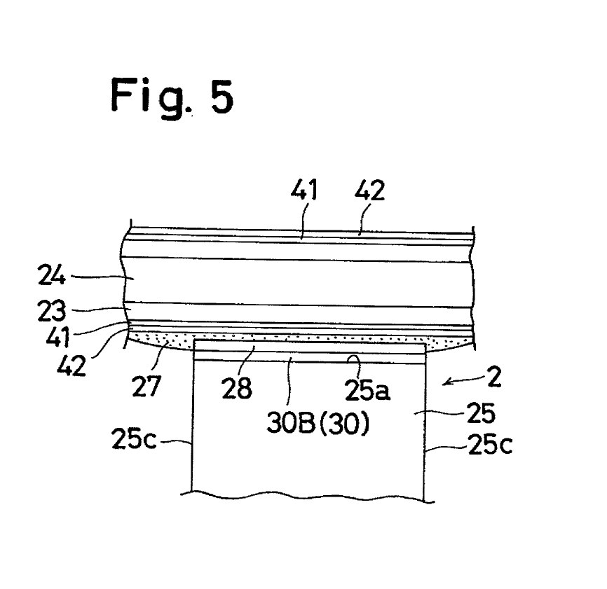

According to the first embodiment, as shown in FIG. 2 and FIG. 3, one end (30A) of the Ni system plating layer 30 is joined to the first electrode 21 of the first board 22 by the solder layer 27 for joining the thermoelectric chips. Based on this process, each thermoelectric chip 25 is joined to the first electrode 21 of the first board 22. Also, shown in the FIG. 5, the other end of the Ni system plating layer 30B (30) is joined to the second electrode 23 of the second board 24 with the solder layer 27 for joining the thermoelectric chips. Based on this process, each thermoelectric chip 25 is joined to a second electrode 23 of the second board 24. Consequently, a plurality of the thermoelectric chips 25 are electrically connected to the first electrode 21 and to the second electrode 23, being aligned between the first board 22 and second board 24.

According to the first embodiment, as shown in FIG. 3, a first intermediary Ni system plating layer 41 is layered on the first electrode 21 of the first board 22 to prevent the first electrode 21 from oxidization and so on. Furthermore, a second intermediary plating layer 42 which is made of gold is layered on the first intermediary plating layer 41 to prevent the first electrode 21 from oxidization and so on. The same can be said to the other end of the Ni system plating layer 30B (30) in the second board 22 side. With respect to the thermoelectric module 2 of the first embodiment of this invention, the solder layer 27 for joining the thermoelectric chips is formed with an Sn—Sb alloy of Sn based, and Sb is contained within a range of 6-15% by weight and the remaining composite includes impurities which cannot be avoided or removed and Sn. In other words, the solder layer 27 for joining the thermoelectric chips is formed with the Sn—Sb alloy with enriched Sb. By enriching Sb, the connecting strength of the chip 25 is secured by the solder layer 27, and melting point (solidus temperature) of the solder layer 27 for joining the thermoelectric chips becomes higher than the case of less Sb containing solder layer.

According to the first embodiment, when soldering, as shown schematically in FIG. 4, Sn and Sb which compose the solder layer 27 for joining the thermoelectric chips are diffused and moved to both ends 30A and 30B of the Ni system plating layer 30, while Ni which is contained in both ends 30A and 30B of the Ni system plating layer 30 are diffused and moved to the solder layer 27 side. Consequently, an alloyed reinforcing layer 28 of the Ni—Sn—Sb system (a first alloyed reinforcing layer), which is effective in improving the connection strength, can be formed between the solder layer 27 and both ends 30A and 30B of the Ni system plating layer 30. As a result, the improvement of the connection strength of the thermoelectric chip 25 can be achieved.

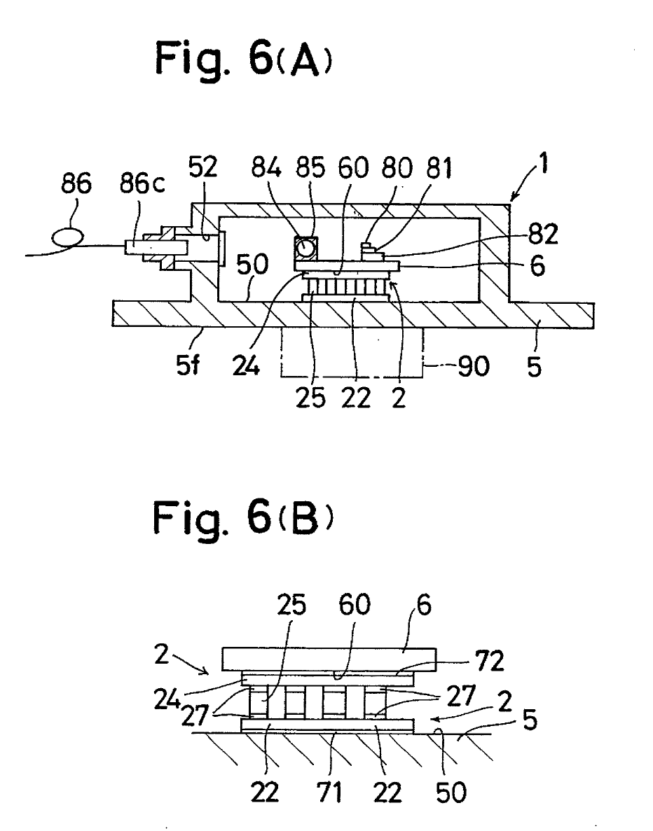

A fiber floodlight device 1 with respect to the first embodiment shown in FIG. 6 (A) has the thermoelectric module 2, a metallic (material: copper-tungsten system) package 5, and a metallic (material: copper-tungsten system) heat transfer block 6. The package 5 has a flat mounting surface 50 to mount the thermoelectric module 2 and a fiber inserting hole 52 which inserts an optical fiber 86. An edge portion of the optical fiber 86 is inserted through the fiber inserting hole 52, and the fiber inserting hole 52 is installed by an installation tool ferrule 86c. A laser diode 80 (a subject) which functions as a light emitting element is mounted on the heat transfer block 6 through a heat sink 81 and a chip carrier 82, and a lens 84, which is used for focusing a laser beam from the laser diode 80 and floodlighting the light to the optical fiber 86, is also mounted on the beat transfer block 6 through a lens holder 85.

According to the fiber floodlight device 1, if an environmental temperature of the laser diode 80 changes, a wavelength of a laser beam from the laser diode 80 is a affected by the temperature change. However, according to the first embodiment, if the electricity is supplied from a feeding portion 39 of the thermoelectric module 2, because of a thermoelectric function, a heat radiation action occurs in the first board 22 side of the thermoelectric module 2, and a cooling action occurs in the second board 24 side. Consequently, the heat transfer block 6, which is joined to the second board 24, is cooled, and eventually the laser diode 80 is cooled. As a result, the change of the wavelength of the laser beam is avoided and therefore, the fiber floodlight device 1 becomes suitable for multiplex transmission of the laser beam.

Upon assembling the fiber floodlight device 1, as specified above, the thermoelectric module 2 is prepared. The thermoelectric module contains the thermoelectric chip 25 which is secured between the first board 22 and the second board 24 by the solder layer 27 for joining the thermoelectric chips. Then, as identical with the known method, the first board 22 of the thermoelectric module 2 and the mounting surface 50 of the package 5 are joined with a first solder layer 71. When soldering the above portions, a heater 90 (of FIG. 6(A)) is placed on an outer surface 5f of the package 5 and by activating the heater 90, the package 5, the thermoelectric module 2, and the heat transfer block 6 are heated. Because of the heat from the heater 90, the solder material which becomes the first solder layer 71 and solder material which becomes a second solder layer 72 are melted and solidified, forming the first solder layer 71 and the second solder layer 72. In this case, considering the location of the heater 90, the temperature of one side which is closest to the heater 90 becomes the highest, the temperature of the other side which is the furthest to the heater 90 becomes the lowest, and the temperature of the thermoelectric module becomes an intermediate temperature, In addition, the heater 90 has a temperature regulation function which can adjust and control the heating temperature precisely.

Upon soldering, if the solder layer 27 for joining the thermoelectric chips of the thermoelectric module 2 is melted and solidified by mistake, the thermoelectric chip 25 which comprises the thermoelectric module 2 is misaligned, causing a disconnection of the electrical contact and consequently causing the dysfunction of the basic performance of the thermoelectric module 2. However, according to the first embodiment, because the solder layer 27 which joins the thermoelectric chip 25 of the thermoelectric module 2 contains enriched Sb, the melting temperature of the solder layer 27 becomes higher. Therefore, assuming a temperature Tm as the melting temperature of the solder layer 27 which joins the thermoelectric chip 25, a temperature T1 as a melting temperature of the first solder layer 71, and a temperature T2 as a melting temperature of the second solder layer 72, the relationship among them is established as Tm(solidus temperature)>T1(liquidus temperature)≧T2(liquidus temperature). By establishing the temperature relationship, a concern about inadvertent melting of the solder layer 27, which is joining the thermoelectric chip 25 in the thermoelectric module 2 is cleared. and the disconnection of the electrical connection of the thermoelectric chip 25 can be avoided. Therefore, this temperature relationship of Tm>T1≧T2 can contribute to the maintenance of the performance of the thermoelectric module 2.

In other words, there is a case in which soldering of the package 5 and the thermoelectric module 2 with the first solder layer 71 and soldering of the thermoelectric module 2 and the heat transfer block 6 with the second solder layer 72 are enforced at the same time. In this case, the temperature relationship is established as Tm (solidus temperature)>T1(liquidus temperature)≧T2 (liquidus temperature). This is to prevent the solder layer 27 for joining the thermoelectric chip 25 which is mounted on the thermoelectric module 2 from melting when the package 5 and the heat transfer block 6 are soldered to the thermoelectric module 2 by melting the first solder layer 71 and the second solder layer 72.

Also, there is another case in which after the first soldering of the package 5 and the thermoelectric module 2 with the first solder layer 71, the second soldering of the thermoelectric module 2 and the heat transfer block 6 is conducted. In this case, the temperature relationship for the first soldering is established as Tm (solidus temperature)>T1(liquidus temperature). This is to prevent the solder layer 27 for soldering the thermoelectric chip 25 of the thermoelectric module 2 from melting during the first soldering by the first solder layer 71. Also, in the case of the second soldering, the temperature relationship is established as T1(solidus temperature)>T2(liquidus temperature). This is to prevent the first solder layer 71 from melting when soldering the heat transfer block 6 by melting the second solder layer 72 for joining the thermoelectric chip 25 of the thermoelectric module. Even when soldering with this sequence, the temperature relationship Tm(solidus temperature)>T1(liquidus temperature)≧T2(liquidus temperature) is maintained.

According to the first embodiment in which the temperature relationship is established, as shown in the above, a concern about inadvertent melting of the solder layer 27, which is assembling the thermoelectric chip, can be prevented. Therefore, this temperature relationship provides more choices of the compositions for the first solder layer 71 and the second solder layer 72 according to the manufacturing environment, and makes easier for users to meet their demands. For instance, as for the first solder layer 71 of the package 5, Sn-2%Ag-0.5%Cu-7.5%Bi can be adopted. When this composition is adopted to the first solder layer 71, a composition of the second solder layer 72 of the heat transfer block 6 can be chosen from Sn-3.2%Ag-2.7%In-2.7%Bi, Sn-3.5%Ag-6%In-3%Bi, Sn-2%Ag-0.5%Cu-7.5%Bi, Sn-8.8%Zn, Sn-8%Zn-3%Bi, Sn-7.5%Zn-3%Bi, Sn-2%Zn-0.2%Cu-2%Bi, Sn-58%Bi, and Sn-57%Bi-1%Ag. The percentage shows % by weight.

Also, as for the first solder layer 71 of the package 5, Sn-2.8%Ag-1%Bi-0.5%Cu can be adopted. When this composition is adopted to the first solder layer 71, a composition of the second solder layer 72 of the heat transfer block 6 can be chosen from Sn-3.5%Ag-3%In-0.5%Bi, Sn-3.2%Ag-2.7%In-2.7%Bi, Sn-3.5%Ag-6%In-3%Bi, Sn-3.5%Ag-5%Bi-0.5%Cu, Sn-2.8%Ag-1%Bi-0.5%Cu, Sn-2%Ag-7.5% Bi-0.5%Cu, Sn-3%Ag-0.7% Cu-1%B-2.5%In, Sn-8.8%Zn, Sn-8%Zn-3%Bi, Sn-7.5%Zn-3%Bi, Sn-8%Zn-0.2%Cu-2%Bi, Sn-58%Bi, and Sn-57%Bi-1%Ag. Furthermore, as for the second solder layer 71 of the package 5, Sn-3.5%Ag-5%Bi-0.5%Cu can be adopted. When this composition is adopted to the first solder layer 71, a composition of the second solder layer 72 of the heat transfer block 6 can chosen from Sn-3.2%Ag-2.7%In-2.7%Bi, Sn-3.5%Ag-6%In-3%Bi, Sn-3.5%Ag-0.5%Cu-5%Bi, Sn-2%Ag-0.5%Cu-7.5%Bi, Sn-8.8%Zn, Sn-8%Zn-3%Bi, Sn-7.5%Zn-3%Bi, Sn-8%Zn-0.2%Cu-2%Bi, Sn-58%Bi, and Sn-57%Bi-1%Ag. However, these compositions are not finite.

According to the first embodiment, because the alloyed reinforcing layer 28 of the Ni—Sn—Sb system (the first alloyed reinforcing layer) is formed in a boundary between the solder layer 27 for joining the thermoelectric chips and the Ni system plating layer 30, the connection strength of the chip 25 is improved. In other words, although the melting point of the solder material which forms the solder layer 27 for joining the thermoelectric chips is high, peeling of a boundary surface of the thermoelectric chip 25 is prevented. Therefore, the alloyed reinforcing layer 28 of the Ni—Sn—Sb system can maintain its performance of the thermoelectric chip 25.

Second Embodiment

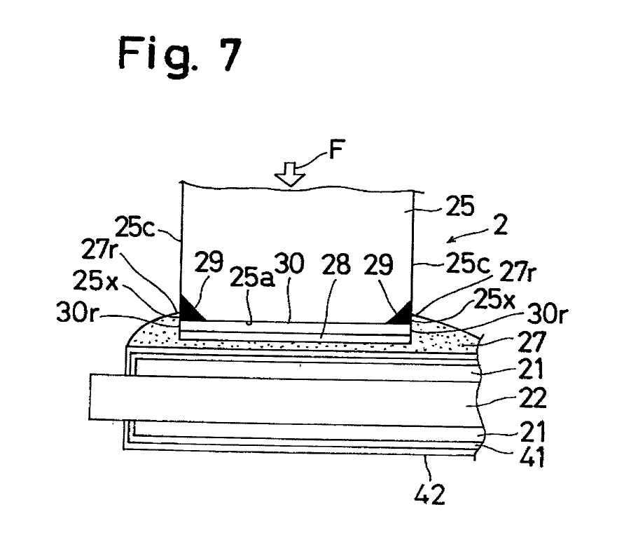

The second embodiment of this invention will be described with reference to FIG. 7. A structure of a fiber floodlight device with respect to the second embodiment is fundamentally identical with the structure of the fiber floodlight device of the first embodiment, and functions of the fiber floodlight device of the second embodiment are also fundamentally identical with the fiber floodlight of the first embodiment. Therefore, the fiber floodlight with respect to the second embodiment is mounted with the thermoelectric module 2 which contains a cooling function.

As for the second embodiment, a solder layer 27 for joining a thermoelectric chip 25 of the thermoelectric module 2 is also formed with an Sn—Sb alloy of Sn based, containing Sb within a range of 6-15% by weight, and the rest is inevitable impurities and Sn. In other words, the solder layer 27 for joining the thermoelectric chips is formed with the Sn—Sb alloy with enriched Sb. By this composition, a melting point of the solder layer 27 for joining the thermoelectric chips increases, contributing to maintain the relationship of Tm>T1≧T2.

When soldering of the solder layer 27, as identical with the first embodiment, Sn and Sb which compose the solder layer 27 for joining the thermoelectric chips are diffused in the Ni system plating layer 30, while Ni which is contained in the Ni system plating layer 30 is diffused in the solder layer 27 side. Consequently, an alloyed reinforcing layer 28 of an Ni—Sn—Sb system (a first alloyed reinforcing layer), which is effective in improving connection strength, can be formed between the Ni system plating layer 30. As a result, the improvement of the connection strength of the thermoelectric chip 25 can be achieved.

According to the second embodiment, as shown in FIG. 7, the thermoelectric chip 25 contains a non-plated side face 25c, which is not covered by the Ni system plating layer 30. The non-plated side face 25c is formed showing the base plate of the thermoelectric chip 25.

According to the second embodiment, upon soldering, by increasing solder material which composes the solder layer 27 for joining the thermoelectric chips while increasing a pressurization F which pressurizes the thermoelectric chip 25, the solder material is forcibly brought together with an edge 25x of the non-plated side face 25c of the thermoelectric chip 25. Consequently, as shown in FIG. 7, a protuberant portion 27r of the solder layer 27 for joining the thermoelectric chips is directly in contact with the edge 25x of the non-plated side face 25c of the thermoelectric chip

More specifically, as shown in FIG. 7, the protuberant portion 27r of the solder layer 27 for joining the thermoelectric chips is directly in contact with a base metal portion of the non-plated side face 25c of the thermoelectric chip 25, crossing over an end surface 30r of the Ni system plating layer 30. As a result, because of the heat upon soldering the thermoelectric chip 25 with the solder layer 27, a second alloyed reinforcing layer, 29, which is composed of alloying elements (Sn, Sb) of the solder layer 27 for joining the thermoelectric chips, is formed in the edge 25x of the non-plated side face 25c.

The thermoelectric chip 25 with respect to this embodiment is formed with an alloy of Bi—Te system, and connection strength is not so strong. However, as specified above, if the second alloyed reinforcing layer 29 which is composed of alloying elements (Sn, Sb) of the solder layer 27 for joining the thermoelectric chips is formed in the edge 25x of the non-plated side face 25c, the edge 25x of a corner periphery of the thermoelectric chip 25 is reinforced. Therefore, if unexpected external force comes into effect, the second alloyed reinforcing layer 29 can contribute to keep the thermoelectric chip 25 from deformation, and thus, it can contribute to keep the thermoelectric chip 25 from the deterioration of its performance. The reason for forming the second alloyed reinforcing layer 29 is that, if the Sn—Sb system alloy is rich with Sb, Sb is diffused in the base metal of the thermoelectric chip 25 with Sn, which is also contained in the solder layer, while an amount of diffusion of Sb in the solder layer 27 remains secured, being able to form the alloyed reinforcing layer which is effective in improving the connection strength of the edge of the corner periphery of the thermoelectric chip 25.

When the thermoelectric chip 25 is formed with an Bi—Te—Sb system alloy, if only Sn is diffused the thermoelectric chip 25, because the fluctuation of the composition of the Bi—Te—Sb system alloy which comprises the thermoelectric chip 25 increases, there is a possibility that the basic thermoelectric functions of the thermoelectric chip 25 may be affected by the fluctuation. However, according to the second embodiment in which the solder layer 27 for joining the thermoelectric chips is rich with Sb, under a circumstance in which the thermoelectric chip is formed with the Ni—Te—Sb system alloy, because Sb other than Sn is also diffused into the Bi—Te—Sb system alloy, and consequently Sb reduces an absolute quantity of Sn. Therefore, dysfunctions of the thermoelectric chip 25 caused by the diffusion of Sn can be prevented. Furthermore, because Sb, which is one of the elements of the base metal, other than Sn is also diffused into the thermoelectric chip 25 which is formed with the Bi—Te—Sb system alloy, compared to the case when only Sn is diffused into the base metal of the chip 25, the diffusion of Sb contributes to prevents from changes of the composition of the Bi—Te—Sb system alloy, which composes the thermoelectric chip 25. As a result, the diffusion of Sb contributes to prevent the thermoelectric function of the thermoelectric chip 25 from being affected by the diffusion of Sn.

(Experimental Test Examples)

With respect to the thermoelectric module 2 of the first embodiment, by changing the content of Sb in the solder layer 27 for joining the thermoelectric chips from 5% through 18%, the melting point (liquidus temperature, solidus temperature), wettability of the solder layer 27, the connection reliability of the thermoelectric chip 25 of the thermoelectric module 2, and the thermoelectric performance of the thermoelectric module 2 were tested respectively. The results of the tests are shown in Table 1. As for a measurement of the melting point, the differential thermal analysis was adopted. As for the reliability of the connection of the thermoelectric module 2, after a shearing load was imposed on the solder layer 27 for joining the thermoelectric chips, a condition of a boundary surface of the solder layer 27 for joining the thermoelectric chips was examined. As for the thermoelectric performance of the thermoelectric module 2, the performance was assessed when the module reached a maximum temperature of the thermoelectric module 2.

As shown in Table 1, if the content of Sb is more than 6% by weight, the melting point (liquidus temperature, solidus temperature) is relatively high as a lead-free solder, being able to satisfy the relationship Tm>T1≧T2. If the relationship is Tm>T1≧T2, as specified above, even when the temperature of the beater 90 changes in some degree, the concern about the inadvertent melting of the solder layer 27 for joining the thermoelectric chips of the thermoelectric module 2 is cleared. Therefore, this temperature relationship provides more choices of the compositions for the first solder layer 71 and the second solder layer 72, making easier for users to meet their demands. Also, if the content of Sb in the solder material which forms the solder layer 27 exceeds 15%, the wettability of the solder decreases, making difficult to carry out soldering. As shown in Table 1, judging the wettability of the solder, the connection strength, and the thermoelectric performance comprehensively, it was the most ideal when the content of Sb in the solder material was 6 to 15%.

TABLE 1

| | | | Temperature | | | |
|---|---|---|---|---|---|---|
| | | | with respect | | | |
| | | | to the | | | |
| | | | Melting, ° C. | | | |
| | | | Solidus | Wettability | Reliability | |
| | | | temperature/ | of Soldering | of Joining | |
| Test | Weight % | | Liquidus | (wetting | (Connecting | Thermoelectric |
| example | of Sb | Sn | temperature | performance) | Strength) | Performance |
| 1 | 5 | Remained | 236/240 | ⊚ | Δ | Δ |
| 2 | 6 | Remained | 240/250 | ⊚ | ◯ | ◯ |
| 3 | 8 | Remained | — | ⊚ | ⊚ | ⊚ |
| 4 | 10 | Remained | 246/275 | ◯ | ⊚ | ⊚ |
| 5 | 12 | Remained | — | ◯ | ⊚ | ⊚ |
| 6 | 14 | Remained | 246/293 | ◯ | ⊚ | ⊚ |
| 7 | 15 | Remained | 246/298 | ◯ | ⊚ | ◯ |
| 8 | 16 | Remained | 246/304 | Δ | ◯ | Δ |
| 9 | 18 | Remained | 246/316 | Δ | ◯ | Δ |

According to the invention, since the plating layer for connecting the thermoelectric chips contains SN-based Nn—Sb system alloy including SB of 6 to 15% by weight, the connecting strength has been improved for connecting the chips to prevent peeling thereof.

A thermoelectric module according to the invention, each thermoelectric chip has a non-plating side surface without Ni system plating layer and the solder layer for joining the thermoelectric chips is directly in contact with an edge of the non-plating side surface and a second reinforcing layer in which Sb of the solder layer is diffused at the edge of the non-plating side surface of the thermoelectric chip. It is advantageous to restrain the deformation of the chips when unexpected exterior force is applied thereto due to the reinforcing layer provided at the corner of the chip. It is also advantageous to improve the thermoelectric characteristic of the thermoelectric chip.

A method for making a thermoelectric module according to the invention, the method comprises the following steps:

preparing a first board having a first electrode, a second board having a second electrode opposing the first electrode, a plurality of thermoelectric chips made of thermoelectric material, each outer surface of the thermoelectric chips being plated with an Ni system plating layer and having a non-plating side surface without being plated with the Ni system plating layer, a lead free solder material comprised of Sn based Sn—Sb system alloy containing Sb of 6-15% by weight and a reinforcing layer of Ni—Sn—Sb system alloy for joining the thermoelectric chip; joining the Ni system plating layer of the thermoelectric chips by soldering with the lead free solder material with the first board having the first electrode and the second board having the second electrode for placing the thermoelectric chips between the first board having the first electrode and the second board having the second electrode and electrically connecting the thermoelectric chips to the first board having the first electrode and the second board having the second electrode to form the thermoelectric module; forming a first reinforcing layer of Ni—Sn—Sb system alloy between a solder layer formed by the melted and solidified soldering material and the Ni system plating layer; and forming a second reinforcing layer of diffused Sb from the soldering material to an edge of the non-plating side surface of the thermoelectric chip by forcibly contacting the soldering material with the edge of the non-plating side surface of the thermoelectric chip. According to this method, the reinforcing alloy layer formed by the alloy elements Sn, Sb diffused from the solder layer for chip connecting and it is advantageous for restraining the deformation of the chips when unexpected exterior force is applied thereto.

A floodlight device using the thermoelectric device according to the invention, the floodlight device includes the package for mounting the thermoelectric module and further includes a fiber inserting hole for inserting an optical fiber therethrough, the heat transfer block further includes a light emitting element for emitting laser beam to the optical fiber inserted in the fiber inserting hole.

This will increase the connecting strength of the thermoelectric chips to restrain the peeling thereof.

(Others) According to the first and the second embodiments, although the laser diode 8 as a light emitting element is mounted on the heat transfer block 6, it is not limited to this and a photo acceptance unit may be mounted on the heat transfer block 6 instead. This invention is not limited to the first and the second embodiments shown in the above description and attached drawings of FIG. 1 to 6, and it is changes therefore can be made within the scope of the content of this invention.

According to this invention, while this invention promotes a lead-free solder layer for joining the thermoelectric chips of the thermoelectric module and improves the connecting strength of the thermoelectric chip. Therefore, it contributes in maintaining the thermoelectric performance of the thermoelectric chip.

According to the thermoelectric device with respect to this invention, the invention can maintain the thermoelectric performance of the thermoelectric module. According to a fiber floodlight with respect to this invention, because the invention can maintain the thermoelectric performance of the thermoelectric module, it can cool the light emitting elements such as the laser diode, it can prevent the changes of the wavelength of the light of the light emitting elements such as the laser diode, and therefore it suits multiplex transmission.

The invention has thus been shown and described with reference to specific embodiments, however, it should be understood that the invention is in no way limited to the details of the illustrated structures but changes and modifications may be made without departing from the scope of the appended claims.

What is claimed is:

1. A thermoelectric module comprising:
a first board having a first electrode;
a second board having a second electrode opposing the first electrode; and
a plurality of thermoelectric chips made of thermoelectric material, each outer surface of the thermoelectric chips being plated with an Ni system plating layer, characterized in that the Ni system plating layer of the thermoelectric chip is joined to the first electrode of the first board and the second electrode of the second board by a lead free solder layer for connecting each thermoelectric chip disposed between the first electrode of the first board and the second electrode of the second board with the first electrode of the first board and the second electrode of the second board and that the lead free solder layer is comprised of Sn based Sn—Sb system alloy containing Sb of 6-15% by weight and a reinforcing layer of Ni—Sn—Sb system alloy is formed between the lead free solder layer and the Ni system plating layer.

2. A thermoelectric module according to claim 1, wherein each thermoelectric chip has a non-plating side surface without Ni system plating layer and the solder layer for joining the thermoelectric chips is directly in contact with an edge of the non-plating side surface and a second reinforcing layer in which Sb of the solder layer is diffused at the edge of the non-plating side surface of the thermoelectric chip.

3. A method for making a thermoelectric module, comprising the steps of:
preparing a first board having a first electrode, a second board having a second electrode opposing the first electrode, a plurality of thermoelectric chips made of thermoelectric material, each outer surface of the thermoelectric chips being plated with an Ni system plating layer and having a non-plating side surface without being plated with the Ni system plating layer, a lead free solder material comprised of Sn based Sn—Sb system alloy containing Sb of 6-15% by weight and a reinforcing layer of Ni—Sn—Sb system alloy for joining the thermoelectric chip;
joining the Ni system plating layer of the thermoelectric chips by soldering with the lead free solder material with the first board having the first electrode and the second board having the second electrode for placing the thermoelectric chips between the first board having the first electrode and the second board having the second electrode and electrically connecting the thermoelectric chips to the first board having the first electrode and the second board having the second electrode to form the thermoelectric module;
forming a first reinforcing layer of Ni—Sn—Sb system alloy between a solder layer formed by the melted and solidified soldering material and the Ni system plating layer; and
forming a second reinforcing layer of diffused Sb from the soldering material to an edge of the non-plating side surface of the thermoelectric chip by forcibly contacting the soldering material with the edge of the non-plating side surface of the thermoelectric chip.

4. A thermoelectric device having the thermoelectric module according to claim 1, having:
a package having an mounting surface for mounting the thermoelectric module;
a heat transfer block for heating or cooling an object mounted thereon;
a first solder layer for joining the first board of the thermoelectric module with the mounting surface of the package;
a second solder layer for joining the second board of the thermoelectric module with the heat transfer block, wherein each temperature relation is defined by Tm>T1≧T2, wherein Tm represents a temperature for melting the soldering material for joining the thermal chips, T1 represents a temperature for melting the first solder layer and T2 represents a temperature for melting the second solder layer.

5. A thermoelectric device having the thermoelectric module according to claim 2,having:
a package having an mounting surface for mounting the thermoelectric module;
a heat transfer block for heating or cooling an object mounted thereon;
a first solder layer for joining the first board of the thermoelectric module with the mounting surface of the package;
a second solder layer for joining the second board of the thermoelectric module with the heat transfer block, wherein each temperature relation is defined by Tm>T1≧T2, wherein Tm represents a temperature for melting the soldering material for joining the thermal chips, T1 represents a temperature for melting the first solder layer and T2 represents a temperature for melting the second solder layer.

6. A floodlight device using the thermoelectric device according to claim 4, wherein the package for mounting the thermoelectric module further includes a fiber inserting hole for inserting an optical fiber therethrough, the heat transfer block further includes a light emitting element for emitting laser beam to the optical fiber inserted in the fiber inserting hole.
